(19) United States
(12) Patent Application Publication
(10) Pub. No.: US 2026/0044088 A1
(43) Pub. Date: Feb. 12, 2026

(54) IMAGE ACQUISITION DEVICE, IMAGE ACQUISITION METHOD, AND IMAGE ACQUISITION DEVICE CONTROL PROGRAM

(71) Applicant: AUROS TECHNOLOGY, INC., Hwaseong-si (KR)

(72) Inventors: Min Young AHN, Hwaseong-si (KR); Hyun Tae KIM, Hwaseong-si (KR)

(21) Appl. No.: 19/356,227

(22) Filed: Oct. 13, 2025

Related U.S. Application Data
(63) Continuation of application No. PCT/KR2024/005289, filed on Apr. 19, 2024.

(30) Foreign Application Priority Data
Apr. 19, 2023 (KR) 10-2023-0051133
Dec. 7, 2023 (KR) 10-2023-0176363

(51) Int. Cl. G03F 7/00

(52) U.S. Cl. CPC G03F 7/706851; G03F 7/70633; G03F 7/70641; G03F 7/70683; G03F 7/706849

(57) ABSTRACT

Proposed is an image acquisition device and method, which includes a stage on which the sample is arranged, an imaging optical system configured to form an image from light reflected from the marks, an autofocus optical system configured to detect Z-direction positional information of a surface of the sample while changing a position of an observation region of the imaging optical system from a previous measurement position of the sample to a current measurement position of the sample by moving at least one of the stage and the imaging optical system in an X-Y plane, and a focus controller configured to move an objective lens of the imaging optical system toward a Z direction on the basis of the Z-direction positional information and to bring a distance between the surface of the sample and the objective lens closer to a reference distance at which the mark is in focus.

### TECHNICAL FIELD

The present disclosure relates to an image acquisition device and method and, more specifically, to an image acquisition device and method, which acquires images of a plurality of marks while moving, with respect to an imaging optical system, a stage on which a sample with the plurality of marks formed thereon is installed.

### BACKGROUND ART

A plurality of pattern layers is sequentially formed on a semiconductor substrate. In addition, a circuit of a single layer is divided and formed into two patterns through double patterning and the like. Only when these pattern layers or a plurality of patterns of the single layer are accurately formed at a predetermined position, can a desired semiconductor device be manufactured.

Accordingly, in order to ensure whether the pattern layers are accurately aligned, overlay marks are used which are formed simultaneously with the pattern layers.

A method of measuring overlay by using the overlay marks is as follows. First, a single structure, which is part of the overlay mark, is formed simultaneously with the formation of the pattern layer at the pattern layer formed in a previous process, for example, an etching process. Then, in a subsequent process, for example, a photolithography process, the remaining structure of the overlay mark is formed in the photoresist.

Also, the overlay measurement device acquires images of the overlay structure (acquiring images through penetrating the photoresist layer) of the pattern layer formed in the previous process and the overlay structure of the photoresist layer, and an offset value between the centers of these images is calculated and measured to measure the overlay error value.

More specifically, Japanese Patent Application Publication 2020-112807 discloses a method of determining relative misalignment between different layers or different patterns by capturing an image of an overlay mark formed on a substrate, selecting a plurality of working zones from the captured image, and forming and comparing a signal having information about each of the selected working zones.

FIG. 1 is a plan view illustrating an example of an overlay mark. The overlay mark 1 shown in FIG. 1 is provided with four sets of working zones 4, 5, 6, 7. Also, each working zone set 4, 5, 6, 7 is provided with two working zones that are arranged diagonally from each other. Each working zone set 4, 5, 6, 7 is used to measure an overlay error in an X-axis or Y-axis direction of a pattern layer formed together with the corresponding working zone set. In order to prevent an interference phenomenon, structures 2 formed together with a first pattern layer and structures 3 formed together with a second pattern layer are arranged so as not to overlap each other.

Each working zone includes bars arranged at regular intervals from the center of the overlay mark 1 to the outer periphery of the overlay mark 1. Accordingly, periodic signals as shown in FIG. 2 can be obtained respectively from two working zones belonging to the working zone set 4, 5, 6, 7 by using the overlay measurement device. The graph of FIG. 2 may be obtained, for example, from the partial region 8 selected in FIG. 1.

In the graph of FIG. 2, peaks appear at a portion where the bars are arranged. Since the conventional overlay mark 1 has bars arranged periodically, the acquired signal also has periodicity. Also, the overlay is measured through correlation analysis of two periodic signals obtained from the two selected regions 8, 8′

FIG. 3 is a view illustrating measurement sites on a semiconductor wafer as dots. Each dot represents an overlay mark. As shown in FIG. 3, a plurality of overlay marks is formed on a single semiconductor wafer. The overlay mark is formed on a scribe lane of the semiconductor wafer.

The overlay measurement device moves the X-Y stage on which the semiconductor wafer is fixed, positions the overlay mark to be measured under an observation region of the imaging optical system of the overlay measurement device, and then focuses on the overlay mark to be measured by using an autofocus optical system to acquire an image of the overlay mark. The focus may be positioned, for example, between the previous pattern layer and the current pattern layer.

However, the position of the focus may be different for each overlay mark. This is because the height for each position of the semiconductor wafer can be different due to the height difference for each position of the warpage of the semiconductor wafer itself and the chuck fixing the semiconductor wafer. Accordingly, the image of the overlay mark should be acquired each time in a state where the overlay mark to be measured is in focus by using the autofocus optical system. Therefore, in order to shorten the MAM (Move, Acquire, Measure) time, which is one of the performance indicators of the overlay measurement device, it is necessary to reduce the time required for focusing by using the autofocus optical system.

Although the overlay measurement device has been described above as an example, it is advantageous to shorten the time required to focus on the mark to be measured in another image acquisition device which acquires images of a plurality of marks formed at various positions of the sample.

### DOCUMENT OF RELATED ART

(Patent Document 1) Japanese Patent Application Publication No. 2020-112807
(Patent Document 2) Korean Patent Application Publication No. 10-2001-0092740
(Patent Document 3) Korean Patent No. 10-2236184
(Patent Document 4) Korean Patent No. 10-2280137

### DISCLOSURE

### Technical Problem

An objective of the present disclosure is to provide an image acquisition device and method capable of shortening a time required to focus on a mark to be measured in response to the above-described demand. In addition, it is intended to provide an image acquisition device control program.

### Technical Solution

In order to achieve the aforementioned objective, as an image acquisition device configured to acquire images of marks from a sample on which a plurality of marks is formed, the present disclosure provides an image acquisition device, which includes a stage on which the sample is arranged, an imaging optical system configured to form an image from light reflected from the marks, an autofocus optical system configured to detect Z-direction positional information of a surface of the sample while changing a position of an observation region of the imaging optical system from a previous measurement position of the sample to a current measurement position of the sample by moving at least one of the stage and the imaging optical system in an X-Y plane, and a focus controller configured to move an objective lens of the imaging optical system toward a Z direction on the basis of the Z-direction positional information while changing the position of the observation region of the imaging optical system from the previous measurement position of the sample to the current measurement position of the sample and to bring a distance between the surface of the sample and the objective lens closer to a reference distance at which the mark is in focus.

In addition, there is provided an image acquisition device in which the autofocus optical system includes a light source for generating illumination light to irradiate the sample, a light detector configured to receive the reflected light reflected from the sample, a light blocking wheel arranged in front of the light detector, wherein a transmission region, through which the reflected light transmits, and a blocking region, through which the reflected light is blocked, are alternately formed along an angular direction, and a condensing lens configured to condense the reflected light toward the light blocking wheel.

In addition, there is provided an image acquisition device in which the light blocking wheel rotates at a constant speed and periodically blocks the reflected light.

In addition, there is provided an image acquisition device in which the light blocking wheel converts the reflected light into periodic discontinuous light and transmits to the light detector.

In addition, there is provided an image acquisition device in which the light detector is provided with a first sensor and a second sensor arranged side-by-side adjacent to each other on the same plane perpendicular to an optical axis of the reflected light.

In addition, there is provided an image acquisition device in which the autofocus optical system is configured to match phases of a periodic signal from the first sensor and a periodic signal from the second sensor when a focus of the reflected light passing through the condensing lens is positioned at the light blocking wheel.

In addition, there is provided an image acquisition device in which the optical axis of the reflected light passing through the condensing lens is positioned at a boundary between the first sensor and the second sensor.

In addition, there is provided an image acquisition device in which the first sensor and the second sensor are cells of a bi-cell photodiode.

In addition, there is provided an image acquisition device in which the autofocus optical system is configured such that a sign of a phase difference between a periodic signal from the first sensor and a periodic signal from the second sensor when a focus of the reflected light passing through the condensing lens is positioned in front of the light blocking wheel is opposite to a sign of a phase difference between the periodic signal from the first sensor and the periodic signal from the second sensor when the focus of the reflected light passing through the condensing lens is positioned behind the light blocking wheel.

In addition, there is provided an image acquisition device in which the autofocus optical system is configured to detect the Z-direction positional information on the surface of the sample while finely moving at least one of the stage and the imaging optical system on the X-Y plane so that the mark formed at the current measurement position is positioned at a center of the image detector, and the focus controller is configured to move an objective lens of the imaging optical system toward the Z direction on the basis of the Z-direction positional information while finely moving at least one of the stage and the imaging optical system on the X-Y plane so that the mark formed at the current measurement position is positioned at the center of the image detector and to bring the distance between the surface of the sample and the objective lens closer to the reference distance.

In addition, there is provided an image acquisition device in which the sample is a semiconductor wafer and the mark is an overlay mark.

In addition, there is provided an image acquisition device in which the image acquisition device is an overlay measurement device.

In addition, as an image acquisition method configured to acquire images of marks from a sample on which a plurality of marks is formed, the present disclosure provides an image acquisition method, which includes detecting Z-direction positional information of a surface of the sample while changing a position of an observation region of an imaging optical system, which is configured to form an image of light reflected from the marks onto an image detector, from a previous measurement position of the sample to a current measurement position and moving an objective lens of the imaging optical system toward a Z direction on the basis of the Z-direction positional information while changing the position of the observation region of the imaging optical system from the previous measurement position of the sample to the current measurement position so as to bring a distance between the surface of the sample and the objective lens closer to a reference distance at which the mark is in focus.

In addition, there is provided an image acquisition method which further includes detecting the Z-direction positional information of the surface of the sample while finely adjusting the position of the observation region of the imaging optical system so that the mark formed at the current measurement position is positioned at a center of the image detector, and moving the objective lens of the imaging optical system toward the Z direction on the basis of the Z-direction positional information while finely adjusting the position of the observation region of the imaging optical system so that the mark formed at the current measurement position is positioned at the center of the image detector so as to bring the distance between the surface of the sample and the objective lens closer to the reference distance.

In addition, as a program stored in a storage medium for executing, using a computing device, an image acquisition method for acquiring images of marks from a sample on which a plurality of marks is formed, the present disclosure provides an image acquisition device control program stored in a storage medium in order to execute a step of detecting Z-direction positional information of a surface of the sample while changing a position of an observation region of an imaging optical system, which is configured to form an image of light reflected from the marks, from a previous measurement position of the sample to a current measurement position, and a step of moving an objective lens of the imaging optical system toward a Z direction on the basis of the Z-direction positional information while changing the position of the observation region of the imaging optical system from the previous measurement position of the sample to the current measurement position so as to bring a distance between the surface of the sample and the objective lens closer to a reference distance at which the mark is in focus.

In addition, there is provided an image acquisition device control program that is automatically executed when an autofocus function is executed at least a predetermined number of times within a predetermined time interval set by the computing device.

In addition, there is provided an image acquisition device control program, which is firmware installed in a fixed memory device of the computing device.

### Advantageous Effects

An image acquisition device and method according to the present disclosure can acquire in advance Z-direction positional information of a surface of a sample in the process of changing a position of an observation region of an imaging optical system from a previous measurement position to a current measurement position, and accordingly can move in advance the imaging optical system in a Z-axis direction, such that a distance of moving the objective lens of the imaging optical system toward the Z-axis direction to focus on the mark to be measured is reduced when the mark to be currently measured is positioned at the observation region of the imaging optical system. Therefore, the time required for focusing can be reduced.

### DESCRIPTION OF DRAWINGS

FIG. 1 is a plan view illustrating an example of an overlay mark.

FIG. 2 is a view illustrating a signal obtained from a single working zone of an overlay mark shown in FIG. 1.

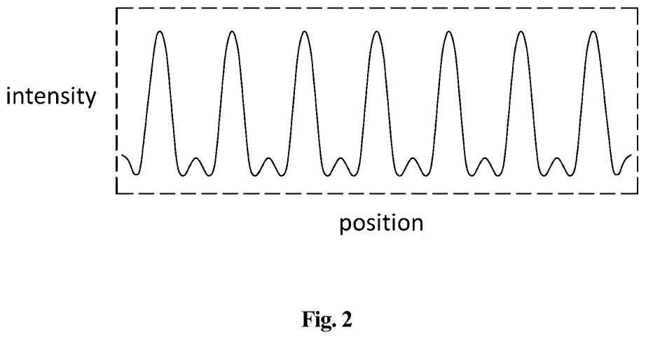

FIG. 3 is a view illustrating measurement sites on a semiconductor wafer as dots.

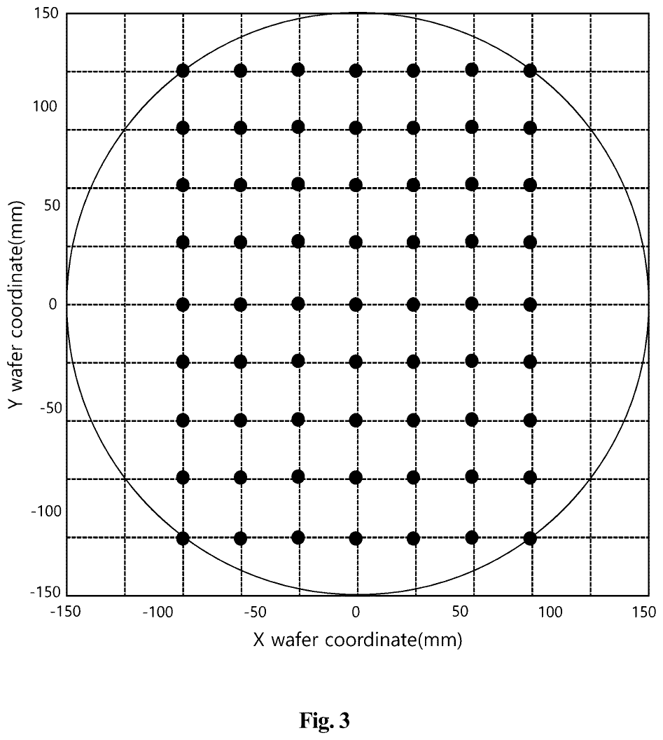

FIG. 4 is a conceptual diagram illustrating an image acquisition device according to an exemplary embodiment of the present disclosure.

FIG. 5 is a conceptual diagram illustrating an autofocus optical system shown in FIG. 4.

FIG. 6 is a view illustrating a light blocking wheel shown in FIG. 5.

FIGS. 7A, 7B, and 7C are views illustrating an operation of an autofocus optical system shown in FIG. 5.

FIGS. 8A and 8B are views illustrating a fine-motion control toward a Z direction.

FIG. 9 is a view illustrating a change over time in a distance between an objective lens and a surface of a sample.

FIG. 10 is a flowchart of an image acquisition method according to an exemplary embodiment of the present disclosure.

### MODE FOR INVENTION

Hereinafter, exemplary embodiments of the present disclosure will be described in detail with reference to the accompanying drawings. However, exemplary embodiments of the present disclosure may be modified in various forms, and the scope of the present disclosure should not be construed as being limited to the exemplary embodiments described below. Exemplary embodiments of the present disclosure may be provided in order to more completely explain the present disclosure to a person having average knowledge in the art. Therefore, the shape of the elements in the drawings may be exaggerated to emphasize a clearer description, and the elements denoted by the same reference numerals in the drawings may refer to the same elements.

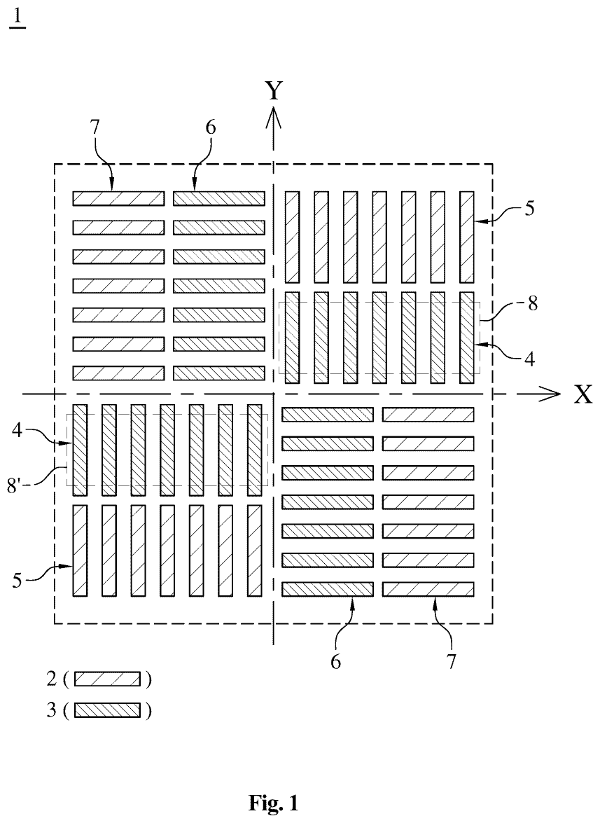

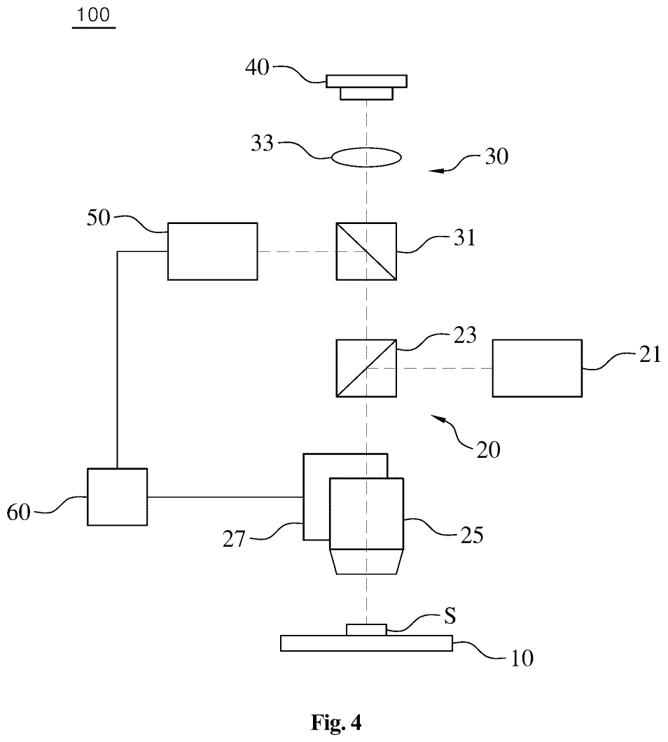

FIG. 4 is a conceptual diagram illustrating an image acquisition device according to an exemplary embodiment of the present disclosure. As shown in FIG. 1, an image acquisition device 100 according to an exemplary embodiment of the present disclosure may include a stage 10, an illumination optical system 20, an imaging optical system 30, an image detector 40, an autofocus optical system 50, and a focus controller 60.

The image acquisition device 100 according to the present disclosure may be used as an overlay measurement device used to measure an interlayer overlay error of a sample (S, for example, a semiconductor wafer) on which a plurality of overlay marks is formed.

The stage 10 may move in the X and Y directions, which are orthogonal to each other, by a horizontal driving unit. The stage 10 may serve to support and move the sample (S) horizontally. The stage 10 may be provided with a vacuum chuck for fixing the sample (S).

The illumination optical system 20 may serve to illuminate the overlay mark of the surface of the sample (S). The illumination optical system 20 may include, for example, an illumination source 21, a beam splitter 23, and an objective lens 25, as shown in FIG. 4. The illumination source 21 may include a light source capable of generating light of a wide wavelength band and replaceable optical filters. A laser diode or a light-emitting diode may be used as the light source. The illumination source 21 may generate illumination of various wavelength bands by combining optical filters and adjusting the wavelength band of the light from the light source.

The beam splitter 23 may be arranged between the illumination source 21 and the objective lens 25, and may serve to transmit the illumination from the illumination source 21 to the objective lens 25.

The objective lens 25 may serve to condense the illumination at the measurement position of the sample (S). The objective lens 25 may be installed on a lens focus actuator 27. The lens focus actuator 27 may be used to adjust the distance between the objective lens 25 and the sample (S) and adjust the focus to be on the overlay mark. The focus control may be performed by moving the objective lens 25 toward the Z direction.

The imaging optical system 30 may serve to form an image of the light reflected from the overlay mark on the image detector 40. The imaging optical system 30 may include, for example, a hot or cold mirror 31 and a tube lens 33. In addition, the imaging optical system 30 may use the objective lens 25 and the beam splitter 23 of the illumination optical system 20.

Like the stage 10, the imaging optical system 30 may also move in the X and Y directions, which are orthogonal to each other, by the horizontal driving unit. As described above, when the stage 10 is configured to move on an X-Y plane, the imaging optical system 30 may be fixed. Conversely, the imaging optical system 30 may move in the X and Y directions, and the stage 10 may be fixed. Hereinafter, it will be described that the imaging optical system 30 is fixed and only the stage 10 is moved.

The hot or cold mirror 31 may serve to prevent the illumination used in the autofocus optical system 50 from being directed to the image detector 40. The hot mirror may have a high transmittance for short-wavelength light and may reflect long-wavelength light. Conversely, the cold mirror may have a high transmittance for long-wavelength light and may reflect short-wavelength light. When the illumination used in the autofocus optical system 50 has a shorter wavelength than the illumination for image acquisition, the cold mirror may be used to reflect the light reflected by the illumination used in the autofocus optical system 50 toward the autofocus optical system 50. Conversely, when the illumination used for the autofocus optical system 50 has a longer wavelength than the illumination for image acquisition, the hot mirror may be used to reflect the light reflected by the illumination used in the autofocus optical system 50 toward the autofocus optical system 50.

The objective lens 25 may collect light reflected from the sample (S). The light collected in the objective lens 25 may be transmitted through the beam splitter 23 and the hot or cold mirror 31 and then focused in the image detector 40 by the tube lens 33.

The image detector 40 may serve to receive light reflected from the overlay mark and to generate an image of the overlay mark. The image detector 40 may be a charge-coupled device (CCD) camera or a complementary metal-oxide semiconductor (CMOS) camera. The image detector 40 may use an imaging element provided with an RGB (red, green, blue) color filter or use a monochrome imaging element.

The autofocus optical system 50 may serve to detect the Z-direction positional information of the surface of the sample (S). That is, information about the distance to the surface of the sample (S) may be detected.

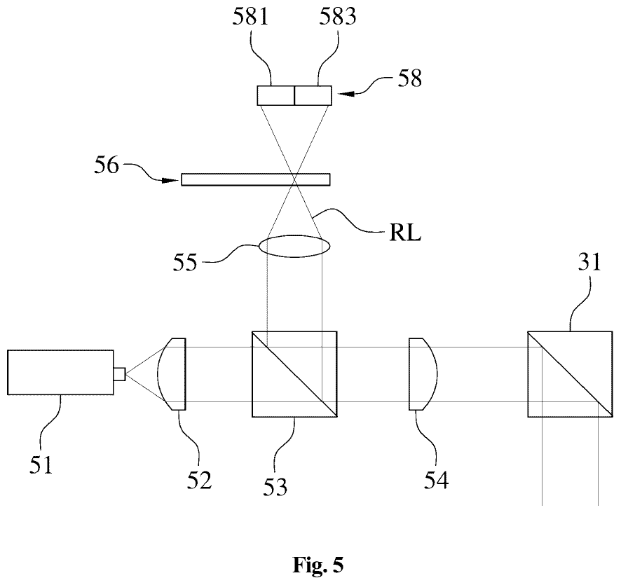

FIG. 5 is a conceptual diagram illustrating an autofocus optical system shown in FIG. 4.

As shown in FIG. 5, the autofocus optical system 50 may include a light source 51, a condensing lens 55, a light blocking wheel 56, and a light detector 58. In addition, an optical lens 52 for refracting the irradiated light from the light source 51, a beam splitter 53, and a cylinder lens 54 may be further included.

A laser diode or a light-emitting diode can be used as the light source 51. The light source 51 may generate irradiation light in an infrared region, for example. The irradiation light may be refracted by the optical lens 52 and then reflected by the mirror 31 after passing through the beam splitter 53 and the cylinder lens 54.

As the optical lens 52, for example, a plano-convex lens may be used. When a laser is used as illumination light, it is preferable to use a polarizing beam splitter as the beam splitter 53. This is because it can minimize the reduction in light intensity during the reflection and transmission.

The cylinder lens 54 may use a cylinder lens 54 of various shapes such as a rectangle, a square, a circle, an ellipse, and the like. The cylinder lens 54 may be a lens that focuses light on a line rather than a dot. The cylinder lens 54 may serve to form a line beam. The use of a line beam may have the advantage of increasing sensitivity due to optical aberration (astigmatism) and enabling more precise measurements.

Also, the irradiation light reflected from the mirror 31 may be transmitted through the beam splitter 33 and then enter the objective lens 25. The objective lens 25 may serve to condense the irradiation light on the measurement region of the wafer (W) and collect the reflected light reflected in the measurement region.

The reflected light collected by the objective lens 25 may be again transmitted through the beam splitter 23 and then reflected by the mirror 31. The reflected light reflected from the mirror 31 may be reflected from the beam splitter 53 toward the light detector 58.

The condensing lens 55 may serve to concentrate the reflected light, which is reflected from the beam splitter 53 toward the light detector 58, toward the light blocking wheel 56. When the height of the surface of the sample (S) is a reference height, the focus of the reflected light passing through the condensing lens 55 may be positioned at the blocking wheel 56.

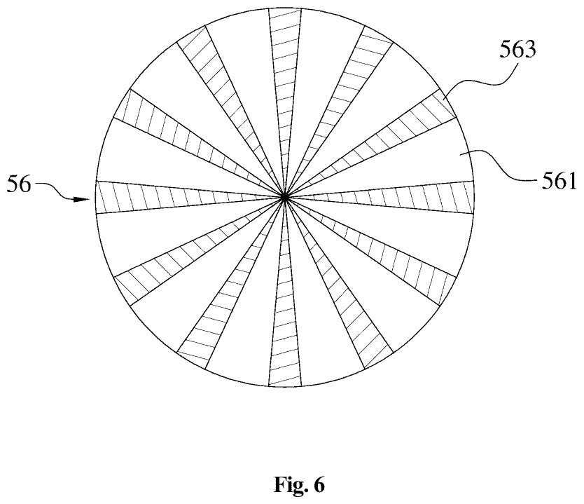

FIG. 6 is a view illustrating a light blocking wheel shown in FIG. 5. As shown in FIG. 6, a transmission region 561 through which reflected light is transmitted and a blocking region 563 through which reflected light is blocked may be formed alternately along the angular direction in the light blocking wheel 56. The blocking region 563 may reflect or absorb reflected light.

The light blocking wheel 56 may rotate at a constant speed and periodically block the reflected light. The rotation axis of the light blocking wheel 56 may be parallel to, and spaced apart from the optical axis of the reflected light (RL). The light blocking wheel 56 may serve to convert the reflected light into periodically discontinuous light and transmit it to the light detector 58.

The light detector 58 may be configured to receive reflected light and to generate two electric signals that are distinguished from each other. When the blocking region 563 and the transmission region 561 are arranged at a regular angular interval, a periodic electric signal in the form closer to a square wave or a sine wave may be generated. By generating such a periodic signal, it is possible to easily and accurately determine whether the two electric signals match. The periodic waveform does not necessarily have to be a square wave or a sine wave, and when the blocking region 563 and the transmission region 561 are not arranged at a regular angular interval, a periodic electrical signal may be generated on the basis of the 360-degree rotation of the light blocking wheel 56.

The light detector 58 may be provided with a first sensor 581 and a second sensor 583 arranged side-by-side adjacent to each other on the same plane perpendicular to the optical axis of the reflected light.

The first sensor 581 and the second sensor 583 may independently generate an electric signal. It is preferable that the first sensor 581 and the second sensor 583 be configured to generate the same electric signal when the same light is incident thereon.

Various types of optical sensors may be used as the first sensor 581 and the second sensor 583. For example, a light diode, a position sensitive device (PSD) sensor, a complementary metal oxide semiconductor (CMOS) sensor, a charge-coupled device (CCD) sensor, and the like may be used. In addition, two separate regions of a single CCD or CMOS sensor may be used as the first sensor 581 and the second sensor 583.

In addition, the light detector 58 may be a bi-cell photodiode. In this case, the two cells of the bi-cell photodiode may serve as the first sensor 581 and the second sensor 583. The first sensor 581 and the second sensor 583 may respectively generate an electric signal proportional to the intensity of reflected light incident thereon.

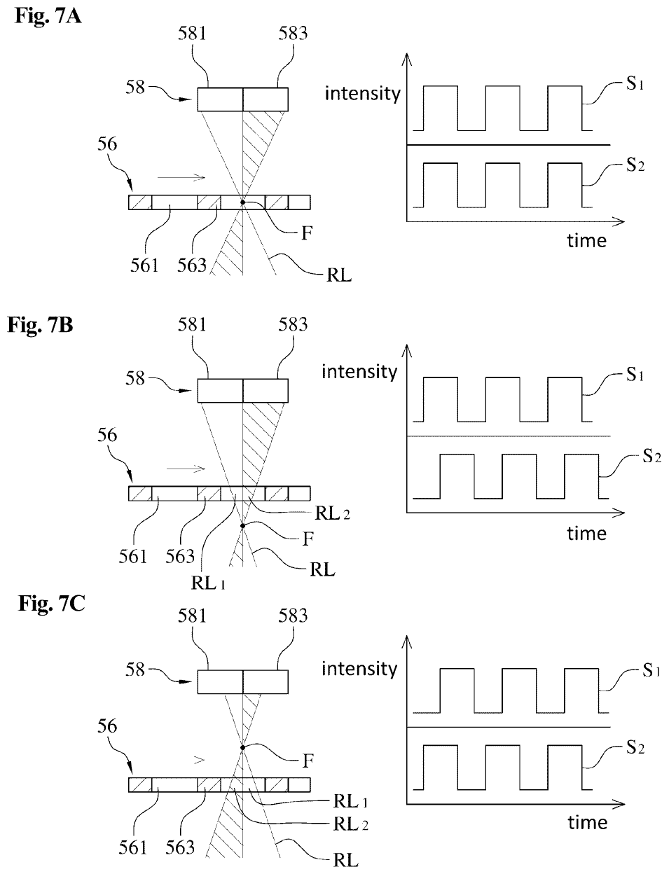

Hereinafter, the operation of the autofocus optical system 50 having the above-described configuration will be described with reference to FIGS. 7A, 7B, and 7C. FIG. 7A illustrates when the focus (F) of the reflected light (RL) is positioned at the light blocking wheel 56. FIG. 7B illustrates when the surface of the sample is lowered and the focus (F) of the reflected light (RL) is positioned in front of the light blocking wheel 56. FIG. 7C illustrates when the surface of the sample is raised and the focus (F) of the reflected light (RL) is positioned behind the light blocking wheel 56.

As shown in FIG. 7A, when the focus (F) of the reflected light (RL) is positioned at the light blocking wheel 56, the phases of the periodic signal (S1) from the first sensor 581 and the periodic signal (S2) from the second sensor 583 may match each other.

However, as shown in FIGS. 7B and 7C, when the focus (F) of the reflected light (RL) is not positioned at the light blocking wheel 56, there is a phase difference between the periodic signal (S1) from the first sensor 581 and the periodic signal (S2) from the second sensor 583.

More specifically, as illustrated in FIG. 7B, when the focus (F) of the reflected light (RL) is in front of the light blocking wheel 56, the reflected light (RL1) incident on the first sensor 581 may first encounter the transmission region 561. Accordingly, the pulse of the periodic signal (S1) from the first sensor 581 may occur earlier than the pulse of the periodic signal (S2) from the second sensor 583.

On the contrary, as illustrated in FIG. 7C, when the focus (F) of the reflected light (RL) is behind the light blocking wheel 56, the reflected light (RL2) incident on the second sensor 583 may first encounter the transmission region 561. Accordingly, the pulse of the periodic signal (S2) from the second sensor 583 may occur earlier than the pulse of the periodic signal (S1) from the first sensor 581.

The autofocus optical system 50 may detect the Z-direction positional information of the surface of the sample (S) through the magnitude and sign of the phase difference between the periodic signal (S1) from the first sensor 581 and the periodic signal (S2) from the second sensor 583.

The focus controller 60 may serve to move the objective lens 25 of the imaging optical system 30 in the Z direction and to bring closer to the distance where the mark formed at the current measurement position is in focus while the stage 10 moves the sample (S) on the X-Y plane. The focus controller 60 may move the objective lens 25 in the Z direction on the basis of the Z-direction positional information received from the autofocus optical system 50.

Even when the focus is on the overlay mark at the previous measurement position, it may not be guaranteed that the focus is exactly correct at the current measurement position. This may be due to issues with the surface precision of the stage 10 or errors caused by the thickness of the sample (S). In addition, when the sample (S) is a semiconductor wafer, a vacuum chuck for supporting the semiconductor wafer may be warped, and the semiconductor wafer may be finely warped.

Likewise, in order to solve the problem that the focus at the previous measurement position and the focus at the current measurement position are different from each other, the focus controller 60 may perform fine-motion control toward the Z direction while the position of the observation region of the imaging optical system 30 changes from the previous measurement position to the current measurement position.

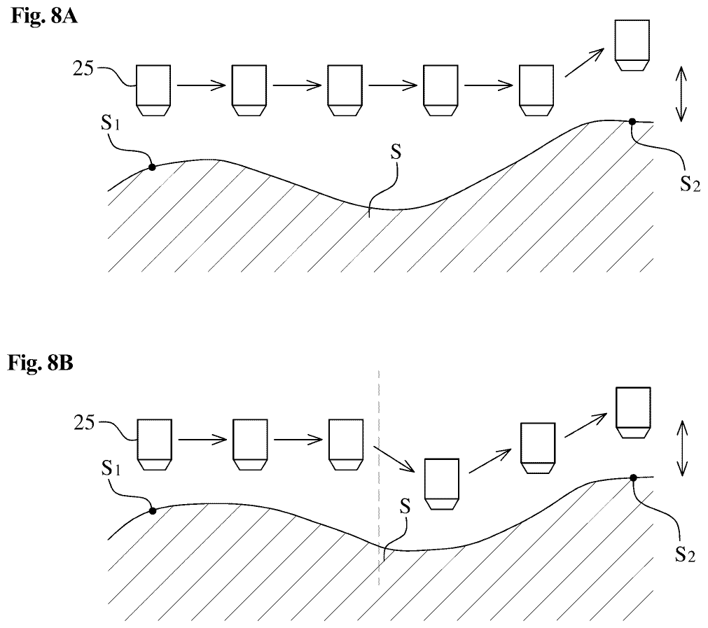

FIGS. 8A and 8B are views illustrating a fine-motion control toward a Z direction. FIG. 8A is a view illustrating a conventional control method, and FIG. 8B is a view illustrating a control method according to the present disclosure.

As shown in FIG. 8A, conventionally, the position of the observation region of the imaging optical system 30 may be changed to the current measurement position (S2) as is in a state where the Z-direction position of the objective lens 25 is fixed on the basis of the previous measurement position (S₁). The position of the observation region of the imaging optical system 30 may be changed by moving the stage 10 and/or the imaging optical system 30.

Also, using the Z-direction positional information from the autofocus optical system 50 at the current measurement position (S₂), the objective lens 25 may be moved toward the Z direction to focus.

As shown in FIG. 8A, when the height difference between the previous measurement position (S₁) and the current measurement position (S₂) is relatively large, the distance that the objective lens 25 has to move toward the Z direction to focus may become longer.

As shown in FIG. 8B, in the present disclosure as well, first, the position of the observation region of the imaging optical system 30 may be changed toward the current measurement position (S₂) in a state where the Z-direction position of the objective lens 25 is fixed on the basis of the previous measurement position (S₁).

Then, when approaching the current measurement position (S₂) to a certain degree, the focus controller 60 may perform the fine-motion control of the objective lens 25 toward the Z direction on the basis of the Z-direction positional information received from the autofocus optical system 50, for example, once every approximately 15 ms. That is, the objective lens 25 may be finely controlled to move toward the Z direction according to the change in the height of the surface of the sample (S), and the distance between the surface of the sample (S) and the objective lens 25 may be adjusted as much as possible to be similar to the reference distance, which is the distance when the focus is on.

Also, when reaching the current measurement position (S₂), the objective lens 25 may be again moved toward the Z direction to focus by using the Z-direction positional information from the autofocus optical system 50.

Since the objective lens 25 is in advance moved to the vicinity of the position when it is focused before reaching the current measurement position (S₂) in the present disclosure, the distance that the objective lens 25 should move during the focusing process may be shortened. Accordingly, the MAM (Move, Acquire, Measure) time may be shortened compared to the conventional method. For example, the MAM time may be reduced by 10% from 100 ms to 90 ms.

Alternatively, while maintaining the entire MAM time, the stability of the measurement can be improved by increasing the “in-position time” (or time in position). The term “in-position time” may refer to the time at which the distance between the objective lens 25 and the surface of the sample (S) may be regarded as the in-focus distance in consideration of the vibration of the overlay measurement device 100. That is, it may refer to the time during which the distance between the objective lens 25 and the surface of the sample (S) falls within the “In-position band” having an allowable width centered on the reference distance, which is the in-focus distance. The allowable width may be determined according to the vibration degree of the overlay measurement device 100.

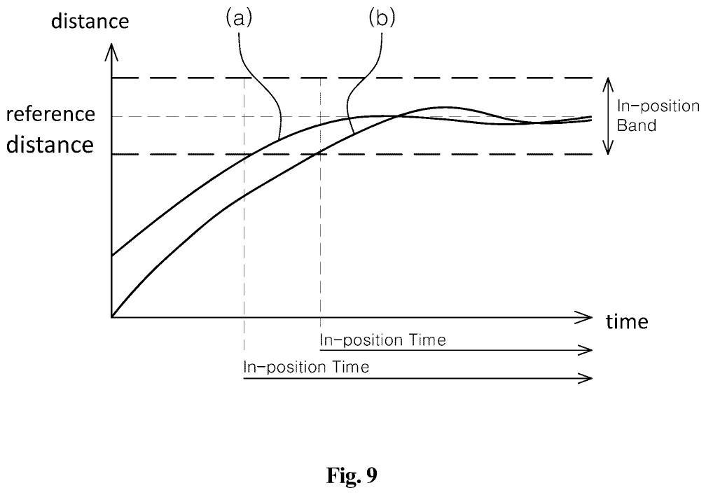

FIG. 9 is a view illustrating a change over time in a distance between an objective lens 25 and a surface of a sample. The graph of FIG. 9A is a graph showing the change in distance according to the control method according to the present disclosure, and the graph of FIG. 9B is a graph showing the change in distance according to the conventional control method.

As shown in FIG. 9, according to the control method according to the present disclosure, the “in-position time” may be lengthened because the “in-position band” is quickly reached. During the secured “in-position time”, the number of “in-position check” may be increased and the measurements may be performed in a more stable manner.

In addition, the focus controller 60 can perform fine-motion control toward the Z direction in the same way even while finely moving the sample (S) in the X and Y directions by using the stage 10 such that the mark of the current measurement position (S₂) is positioned at the center of the image detector 40 after the objective lens 25 reaches the current measurement position (S₂).

That is, after detecting the Z-direction positional information of the surface of the sample (S) while moving the sample (S) such that the mark formed at the current measurement position (S₂) is positioned at the center of the image detector 40, the objective lens 25 of the imaging optical system 30 may be moved toward the Z direction on the basis of the Z-direction positional information while moving the sample (S) such that the mark formed at the current measurement position (S₂) is positioned at the center of the image detector 40, and the distance between the surface of the sample (S) and the objective lens 25 is brought closer to the reference distance.

As the focus controller 60, there is used a computing device such as an MCU (Micro controller unit), a desktop computer, a laptop computer, a smartphone, or a smart pad and the like, which includes a processor, a memory, a fixed memory device (ROM), a storage device such as a hard disk or SSD, a hardware such as a wired or wireless communication device used to receive the Z-direction positional information from the autofocus optical system 50 and to transmit a control signal for controlling the objective lens 25, and a program such as firmware or software installed on a storage medium such as a memory, a fixed memory device, a storage device or the like.

An image acquisition device control program according to an exemplary embodiment of the present disclosure may be installed on the storage medium of the focus controller 60. The focus controller 60 may instruct the processor to perform the Z-direction fine-motion control of the objective lens 25 according to the Z-direction positional information through instructions of the image acquisition device control program.

The image acquisition device control program may be manually executed, or may be automatically executed when an autofocus function is consecutively executed a predetermined number of times, for example, 5 times within a predetermined time interval. This is to prevent the image acquisition device control program from being automatically executed when unnecessary, such as when the autofocus function is used for troubleshooting.

The computing device may be used even for the movement of the stage 10. The movement of stage 10 may be performed, for example, by converting a target position coordinate into a stage coordinate position and transmitting control data to the stage 10.

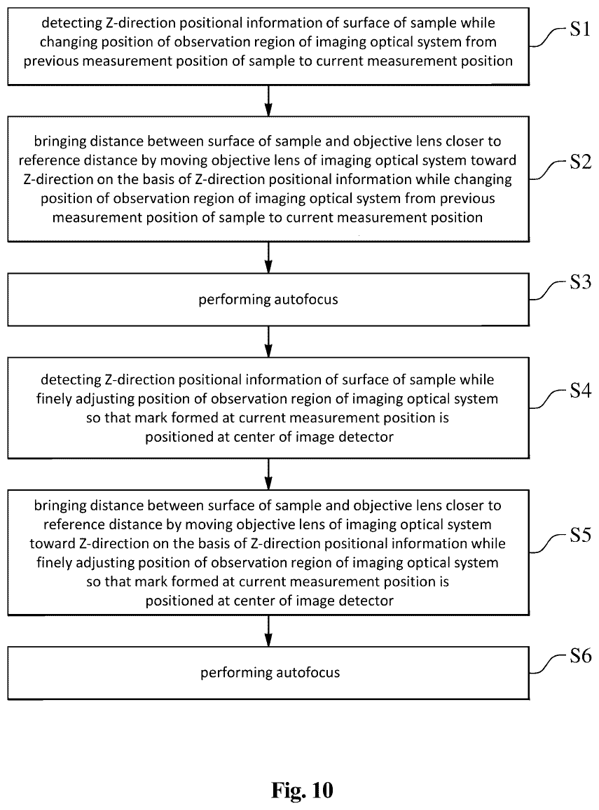

Hereinafter, the operation of the above-described image acquisition device 100 will be described with reference to FIG. 10. FIG. 10 is a flowchart of an image acquisition method according to an exemplary embodiment of the present disclosure.

As shown in FIG. 10, the image acquisition method according to an exemplary embodiment of the present disclosure may include (S1) detecting Z-direction positional information of the surface of the sample (S) while changing a position of an observation region of the imaging optical system 30 from a previous measurement position of the sample (S) to a current measurement position.

This step may detect the Z-direction positional information of the surface of the sample (S) at regular time intervals by using the autofocus optical system 50 while moving the stage 10 and changing the position of the observation region of the imaging optical system 30 from the previous measurement position of the sample (S) to the current measurement position.

Next, while changing the position of the observation region of the imaging optical system 30 from the previous measurement position of the sample (S) to the current measurement position, a step (S2) may be performed which moves the objective lens 25 of the imaging optical system 30 toward the Z direction on the basis of the Z-direction positional information and brings the distance between the surface of the sample (S) and the objective lens (25) closer to the reference distance.

Next, a step (S3) of performing autofocus may be performed.

In this step, the autofocus optical system 50 may be used to focus on the mark to be measured formed at the current measurement position. Since the reference distance is brought closer in advance in the previous step (S2), the objective lens 25 may be moved slightly toward the Z direction to focus on the mark in this step.

Next, a step (S4) may be performed which detects the Z-direction positional information of the surface of the sample (S) while finely adjusting the position of the observation region of the imaging optical system 30 so that the mark formed at the current measurement position is positioned at the center of the image detector 40.

When the mark of the current measurement position enters the observation region of the imaging optical system 30, the Z-direction positional information of the surface of the sample (S) may be detected while finely moving the position of the observation region of the imaging optical system 30 toward the X and Y directions, such that the position of the mark in the image detector 40 is checked and positioned at the center of the image detector 40.

Next, a step (S5) may be performed which moves the objective lens 25 of the imaging optical system 30 toward the Z direction on the basis of the Z-direction positional information while finely adjusting the position of the observation region of the imaging optical system 30 so that the mark formed at the current measurement position is positioned at the center of the image detector 40 so as to bring the distance between the surface of the sample (S) and the objective lens 25 closer to the reference distance.

Next, a step (S6) of performing autofocus may be performed.

In this step, the autofocus optical system 50 may be used to focus on the mark to be measured at the current position. Then, the mark image to be used for measurements may be acquired.

The exemplary embodiments described above may be merely illustrative of the preferred exemplary embodiments of the present disclosure, and the scope of the present disclosure may not be limited to the described exemplary embodiments, and various changes, modifications, or substitutions may be made by those skilled in the art within the technical spirit of the present disclosure and the claims, and it should be understood that such exemplary embodiments fall within the scope of the present disclosure.

### DESCRIPTION OF REFERENCE NUMERALS

S: sample
10: stage
20: illumination optical system
30: imaging optical system
40: image detector
50: autofocus optical system
60: focus controller

1. As an image acquisition device configured to acquire images of marks from a sample on which a plurality of marks is formed, the image acquisition device, comprising:
a stage on which the sample is arranged;
an imaging optical system configured to form an image from light reflected from the marks;
an image detector configured to receive the reflected light and generate a mark image;
an autofocus optical system configured to detect Z-direction positional information of a surface of the sample while changing a position of an observation region of the imaging optical system from a previous measurement position of the sample to a current measurement position of the sample by moving at least one of the stage and the imaging optical system in an X-Y plane; and
a focus controller configured to move an objective lens of the imaging optical system toward a Z direction on the basis of the Z-direction positional information while changing the position of the observation region of the imaging optical system from the previous measurement position of the sample to the current measurement position of the sample and to bring a distance between the surface of the sample and the objective lens closer to a reference distance at which the mark is in focus.

2. The device of claim 1, wherein the autofocus optical system comprises:
a light source for generating illumination light to irradiate the sample;
a light detector configured to receive the reflected light reflected from the sample;
a light blocking wheel arranged in front of the light detector, wherein a transmission region, through which the reflected light transmits, and a blocking region, through which the reflected light is blocked, are alternately formed along an angular direction; and
a condensing lens configured to condense the reflected light toward the light blocking wheel.

3. The device of claim 2, wherein the light blocking wheel rotates at a constant speed and periodically blocks the reflected light.

4. The device of claim 2, wherein the light blocking wheel converts the reflected light into periodic discontinuous light and transmits to the light detector.

5. The device of claim 2, wherein the light detector is provided with a first sensor and a second sensor arranged side-by-side adjacent to each other on the same plane perpendicular to an optical axis of the reflected light.

6. The device of claim 5, wherein the autofocus optical system is configured to match phases of a periodic signal from the first sensor and a periodic signal from the second sensor when a focus of the reflected light passing through the condensing lens is positioned at the light blocking wheel.

7. The device of claim 5, wherein the optical axis of the reflected light passing through the condensing lens is positioned at a boundary between the first sensor and the second sensor.

8. The device of claim 5, wherein the first sensor and the second sensor are cells of a bi-cell photodiode.

9. The device of claim 5, wherein the autofocus optical system is configured such that a sign of a phase difference between a periodic signal from the first sensor and a periodic signal from the second sensor when a focus of the reflected light passing through the condensing lens is positioned in front of the light blocking wheel is opposite to a sign of a phase difference between the periodic signal from the first sensor and the periodic signal from the second sensor when the focus of the reflected light passing through the condensing lens is positioned behind the light blocking wheel.

10. The device of claim 1, wherein the autofocus optical system is configured to detect the Z-direction positional information on the surface of the sample while finely moving at least one of the stage and the imaging optical system on the X-Y plane so that the mark formed at the current measurement position is positioned at a center of the image detector, and
the focus controller is configured to move the objective lens of the imaging optical system toward the Z direction on the basis of the Z-direction positional information while finely moving at least one of the stage and the imaging optical system on the X-Y plane so that the mark formed at the current measurement position is positioned at the center of the image detector and to bring the distance between the surface of the sample and the objective lens closer to the reference distance.

11. The device of claim 1, wherein the sample is a semiconductor wafer and the mark is an overlay mark.

12. The device of claim 1, wherein the image acquisition device is an overlay measurement device.

13. As an image acquisition method configured to acquire images of marks from a sample on which a plurality of marks is formed, the image acquisition method comprising:
detecting Z-direction positional information of a surface of the sample while changing a position of an observation region of an imaging optical system, which is configured to form an image of light reflected from the marks onto an image detector, from a previous measurement position of the sample to a current measurement position; and
moving an objective lens of the imaging optical system toward a Z direction on the basis of the Z direction positional information while changing the position of the observation region of the imaging optical system from the previous measurement position of the sample to the current measurement position so as to bring a distance between the surface of the sample and the objective lens closer to a reference distance at which the mark is in focus.

14. The method of claim 13, further comprising:
detecting the Z-direction positional information of the surface of the sample while finely adjusting the position of the observation region of the imaging optical system so that the mark formed at the current measurement position is positioned at a center of the image detector, and
moving the objective lens of the imaging optical system toward the Z direction on the basis of the Z-direction positional information while finely adjusting the position of the observation region of the imaging optical system so that the mark formed at the current measurement position is positioned at the center of the image detector so as to bring the distance between the surface of the sample and the objective lens closer to the reference distance.

15. As a program stored in a storage medium for executing, using a computing device, an image acquisition method for acquiring images of marks from a sample on which a plurality of marks is formed, the image acquisition device control program executing:
detecting Z-direction positional information of a surface of the sample while changing a position of an observation region of an imaging optical system, which is configured to form an image of light reflected from the marks, from a previous measurement position of the sample to a current measurement position; and
moving an objective lens of the imaging optical system toward a Z direction on the basis of the Z-direction positional information while changing the position of the observation region of the imaging optical system from the previous measurement position of the sample to the current measurement position so as to bring a distance between the surface of the sample and the objective lens closer to a reference distance at which the mark is in focus.

16. The program of claim 15, wherein the image acquisition device control program is automatically executed when an autofocus function is executed at least a predetermined number of times within a predetermined time interval set by the computing device.

17. The program of claim 15, wherein the image acquisition device control program is firmware installed in a fixed memory device of the computing device.
